(19) United States
(12) Patent Application Publication
(10) Pub. No.: US 2026/0190942 A1
(43) Pub. Date: Jul. 2, 2026

(54) MEMBER FOR SEMICONDUCTOR MANUFACTURING APPARATUS

(71) Applicant: NGK INSULATORS, LTD., Nagoya (JP)

(72) Inventors: Seiya INOUE, Nishio (JP); Tatsuya KUNO, Nagoya (JP); Shota YAMAKOSHI, Anpachi-cho (JP); Kanta MIYAMOTO, Handa (JP)

(21) Appl. No.: 19/546,842

(22) Filed: Feb. 23, 2026

Related U.S. Application Data
(63) Continuation of application No. PCT/JP2025/026934, filed on Jul. 30, 2025.

(30) Foreign Application Priority Data
Sep. 3, 2024 (JP) 2024-151453

(51) Int. Cl. H10P 72/72; H10P 72/00

(52) U.S. Cl. CPC H10P 72/722; H10P 72/0432

(57) ABSTRACT

includes a ceramic plate having a wafer placement surface on its upper surface and incorporating an electrode; a base plate which is joined to a lower surface of the ceramic plate via a bonding layer and incorporates a refrigerant flow path; a base plate through-hole which penetrates the base plate in an up-down direction at a position not interfering with the refrigerant flow path, and which has an opening portion chamfered with C-chamfering at C0.5 or more on the ceramic plate side; an insulating tube inserted into the base plate through-hole; a power feeding member inserted into the insulating tube and having a tip electrically connected to the electrode; and an adhesive layer provided between an inner peripheral surface of the base plate through-hole including the opening portion chamfered with C-chamfering and an outer peripheral surface of the insulating tube.

### CROSS-REFERENCE TO RELATED APPLICATION

This application is a continuation application of PCT/JP2025/026934, filed on Jul. 30, 2025, which claims the benefit of priority of Japanese Patent Application No. JP2024-151453 filed on Sep. 3, 2024, the entire contents of which are incorporated herein by reference.

### BACKGROUND OF THE INVENTION

### 1. Field of the Invention

The present invention relates to a member for a semiconductor manufacturing apparatus.

### 2. Description of the Related Art

Conventionally, a member for semiconductor manufacturing apparatus provided with a ceramic plate, a base plate, a base plate through-hole, and a power feeding member has been known. For example, in the member for semiconductor manufacturing apparatus described in PTL 1, the ceramic plate has a wafer placement surface on its upper surface and incorporates a heater electrode. The base plate is joined to a lower surface of the ceramic plate via a bonding layer and incorporates a refrigerant flow path. The base plate through-hole penetrates the base plate in an up-down direction at a position not interfering with the refrigerant flow path and has, on the ceramic plate side, an opening portion chamfered with C-chamfering. The power feeding member is inserted into the base plate through-hole, and its tip is electrically connected to the heater electrode. It is further described that the base plate through-hole may be provided with an insulating tube through which the power feeding member is inserted.

### CITATION LIST

### Patent Literature

PTL 1: JP2023-27641A

### SUMMARY OF THE INVENTION

Meanwhile, in PTL 1, in a case where the base plate through-hole is provided with an insulating tube, it is conceivable to provide an adhesive layer between an inner peripheral surface of the base plate through-hole including the opening portion chamfered with C-chamfering and an outer peripheral surface of the insulating tube (such a configuration is not described in PTL 1). However, when forming the adhesive layer, bubbles may enter a portion surrounded by the opening portion chamfered with C-chamfering and the outer peripheral surface of the insulating tube, and such bubbles have sometimes caused a decrease in the dielectric withstand voltage between the power feeding member and the base plate.

The present invention has been made to solve such a problem, and its primary object is to increase the dielectric withstand voltage between the power feeding member and the base plate, and at the same time to suppress variations in dielectric withstand voltage among products.

[1] A member for semiconductor manufacturing apparatus includes: a ceramic plate having a wafer placement surface on its upper surface and incorporating an electrode; a base plate which is joined to a lower surface of the ceramic plate via a bonding layer and incorporates a refrigerant flow path; a base plate through-hole which penetrates the base plate in an up-down direction at a position not interfering with the refrigerant flow path, and which has an opening portion chamfered with C-chamfering at C0.5 or more on the ceramic plate side; an insulating tube inserted into the base plate through-hole; a power feeding member inserted into the insulating tube and having a tip electrically connected to the electrode; and an adhesive layer provided between an inner peripheral surface of the base plate through-hole including the opening portion chamfered with C-chamfering and an outer peripheral surface of the insulating tube.

In this member for semiconductor manufacturing apparatus, the base plate through-hole has an opening portion chamfered with C-chamfering at C0.5 or more on the ceramic plate side, and the adhesive layer is provided between the inner peripheral surface of the base plate through-hole including the opening portion chamfered with C-chamfering and the outer peripheral surface of the insulating tube. Accordingly, when inserting the insulating tube into the base plate through-hole and bonding it while an adhesive is attached to a bottom surface of the base plate through-hole, even if bubbles occur in the adhesive, the bubbles can sufficiently escape radially outward from the insulating tube; therefore, bubbles can be suppressed from entering the adhesive layer between an upper surface of the insulating tube and the lower surface of the ceramic plate. As a result, the influence of bubbles on the dielectric withstand voltage can be suppressed. Therefore, the dielectric withstand voltage between the power feeding member and the base plate can be increased, and even if the manner in which bubbles occur differs among products, variations in dielectric withstand voltage among products can be suppressed.

In this specification, up and down, left and right, and front and back, for example, are used to describe the present invention, but up and down, left and right, and front and back represent only a relative positional relationship. Thus, when the orientation of the member for a semiconductor manufacturing apparatus is changed, up and down may become left and right, or left and right may become up and down. Such cases are also included in the technical scope of the present invention.

[2] In the above member for a semiconductor manufacturing apparatus (the member for a semiconductor manufacturing apparatus described in [1] above), it is preferable that, when the member for semiconductor manufacturing apparatus is viewed from above, the opening portion of the base plate through-hole and the refrigerant flow path do not overlap each other. If, when the member for semiconductor manufacturing apparatus is viewed from above, the opening portion of the base plate through-hole and the refrigerant flow path overlap, a thickness of a portion of the base plate between the opening portion of the base plate through-hole and the refrigerant flow path tends to become thin, and as a result, there is a possibility that a defect (deformation, cracking, etc.) may occur in the base plate when joining the base plate and the ceramic plate. Here, since, when the member for semiconductor manufacturing apparatus is viewed from above, the opening portion of the base plate through-hole and the refrigerant flow path do not overlap each other, such a possibility is eliminated.

[3] In the above member for a semiconductor manufacturing apparatus (the member for a semiconductor manufacturing apparatus described in [1] or [2] above), it is preferable that the opening portion chamfered with C-chamfering is at C2 or less. A temperature of a wafer placed on the wafer placement surface tends to become high at a portion directly above a central axis of the base plate through-hole. Therefore, if the opening portion of the base plate through-hole exceeds C2 (is too large), heat of the ceramic plate is less likely to escape to the base plate. When the opening portion chamfered with C-chamfering is at C2 or less, it is possible to suppress a decrease in heat escape from the ceramic plate to the base plate. In addition, when the opening portion chamfered with C-chamfering is at C2 or less, the refrigerant flow path can be brought sufficiently close to the base plate through-hole within a range in which the opening portion of the base plate through-hole and the refrigerant flow path do not overlap when the wafer placement table is viewed from above.

[4] In the above member for a semiconductor manufacturing apparatus (the member for a semiconductor manufacturing apparatus described in any one of [1] to [3] above), the adhesive layer may have bubbles between the opening portion of the base plate through-hole and the outer peripheral surface of the insulating tube, and the bubbles may be present at positions separated from the insulating tube. In this manner, the effects of the present invention are more easily achieved.

[5] In the above member for a semiconductor manufacturing apparatus (the member for a semiconductor manufacturing apparatus described in any one of [1] to [4] above), the bonding layer may have a bonding layer through-hole at a position facing the base plate through-hole, and a distance from an outer edge of the opening portion of the base plate through-hole to an inner peripheral surface of the bonding layer through-hole may be 0.5 mm or less. In this manner, even if a space exists between the outer edge of the opening portion of the base plate through-hole and the inner peripheral surface of the bonding layer through-hole, an influence on temperature uniformity of the wafer can be reduced.

[6] The above member for a semiconductor manufacturing apparatus (the member for a semiconductor manufacturing apparatus described in any one of [1] to [5] above), it is preferable that thermal conductivity of the adhesive layer is 0.5 W/mK or more. In this manner, heat of the wafer is more easily conducted to the base plate side through the adhesive layer, and thus temperature uniformity of the wafer is easily maintained.

### BRIEF DESCRIPTION OF THE DRAWINGS

FIG. 1 is a plan view of a wafer placement table 10.

FIG. 2 is a sectional view taken along line A-A in FIG. 1.

FIG. 3 is a partially enlarged view of FIG. 2.

FIGS. 4A to 4D are explanatory diagrams illustrating an adhesive process of an insulating tube 50 according to the present embodiment.

FIGS. 5A to 5D are explanatory diagrams illustrating an adhesive process of an insulating tube 50 according to a comparative embodiment.

FIG. 6 is a graph representing a relationship between a C-value of an opening portion 34c and dielectric withstand voltage-related parameters.

FIG. 7 is a partially enlarged vertical sectional view of another embodiment.

FIG. 8 is a partially enlarged vertical sectional view of another embodiment.

### DETAILED DESCRIPTION OF THE INVENTION

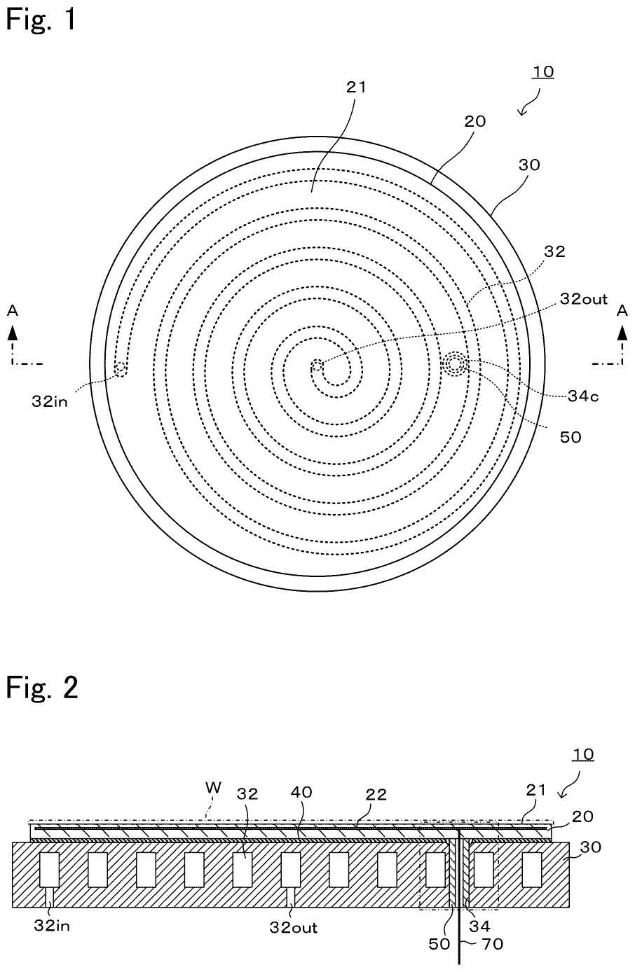

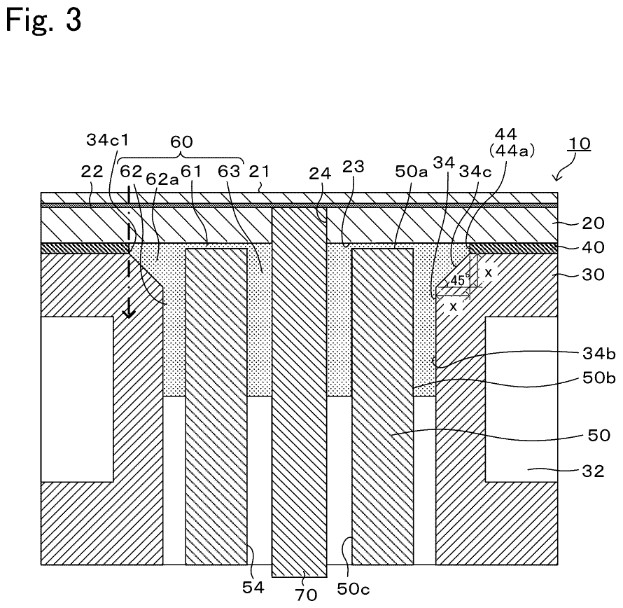

Preferred embodiments of the present invention will be described below with reference to the drawings. FIG. 1 is a plan view of a wafer placement table 10, FIG. 2 is a sectional view taken along line A-A in FIG. 1, and FIG. 3 is a partially enlarged view of FIG. 2 (an enlarged view of the region indicated by the two-dot chain line).

The wafer placement table 10 is an example of the member for semiconductor manufacturing apparatus of the present invention and, as shown in FIG. 2, includes a ceramic plate 20, a base plate 30, a bonding layer 40, a base plate through-hole 34, an insulating tube 50, and a power feeding member 70.

The ceramic plate 20 is a ceramic disk such as an alumina sintered body or an aluminum nitride sintered body (for example, a disk having a diameter of 300 mm and a thickness of 5 mm). An upper surface of the ceramic plate 20 serves as a wafer placement surface 21 on which a wafer W is placed. The ceramic plate 20 incorporates an electrostatic electrode 22. Although not illustrated, an annular seal band is formed along an outer edge of the wafer placement surface 21 of the ceramic plate 20, and a plurality of circular small projections are formed over the entire region inside the seal band. The electrostatic electrode 22 is a planar mesh electrode and is connected, via the power feeding member 70, to an external DC power supply not shown. When a DC voltage is applied to the electrostatic electrode 22, the wafer W is attracted and fixed to the wafer placement surface 21 by electrostatic attraction, and when application of the DC voltage is released, the attraction and fixation of the wafer W to the wafer placement surface 21 is released.

The base plate 30 is a disk having good electrical conductivity and thermal conductivity (for example, a disk having the same diameter as or a diameter larger than that of the ceramic plate 20, and having a thickness of 25 mm). Inside the base plate 30, a refrigerant flow path 32 through which a refrigerant circulates is formed. The refrigerant flowing through the refrigerant flow path 32 is preferably a liquid and is preferably electrically insulating. Examples of electrically insulating liquids include fluorine-based inert liquids. As shown in FIG. 1, the refrigerant flow path 32 is formed in a swirl shape in a one-stroke pattern from one end (an inlet 32in) to the other end (an outlet 32out) over the entirety of the base plate 30 in plan view. A supply port and a recovery port of an external refrigerant device (not shown) are respectively connected to the inlet 32in and the outlet 32out of the refrigerant flow path 32. A refrigerant supplied from the supply port of the external refrigerant device to the inlet 32in of the refrigerant flow path 32 passes through the refrigerant flow path 32 and returns from the outlet 32out of the refrigerant flow path 32 to the recovery port of the external refrigerant device, is temperature-controlled, and is supplied again from the supply port to the inlet 32in of the refrigerant flow path 32. The base plate 30 is connected to a radio-frequency (RF) power supply and is also used as an RF electrode.

As materials for the base plate 30, for example, metallic materials or composite materials of metal and ceramic can be used. Examples of metallic materials include Al, Ti, Mo, or alloys thereof. Examples of composite materials of metal and ceramic include metal matrix composites (MMC) and ceramic matrix composites (CMC). Specific examples of such composite materials include materials containing Si, SiC, and Ti (also referred to as SiSiCTi), materials in which Al and/or Si is impregnated into a SiC porous body, and composite materials of Al2O3 and TiC. As the material of the base plate 30, it is preferable to select one having a thermal expansion coefficient close to that of the material of the ceramic plate 20.

The bonding layer 40 is, here, a metal layer and joins a lower surface of the ceramic plate 20 and an upper surface of the base plate 30. The metal layer can be formed using a metal bonding material (for example, Al-Mg bonding material or Al-Si-Mg bonding material) by well-known thermal compression bonding (TCB).

The base plate through-hole 34 is a substantially cylindrical hole penetrating the base plate 30 in the up-down direction, and is provided so as not to penetrate the refrigerant flow path 32. That is, the base plate through-hole 34 penetrates the base plate 30 in the up-down direction at a position not interfering with the refrigerant flow path 32. The base plate through-hole 34 has, on the ceramic plate 20 side, an opening portion 34c chamfered with C-chamfering at C0.5 or more. Therefore, the opening portion 34c chamfered with C-chamfering forms a tapered surface. “C0.5” means that x=0.5 (mm) in FIG. 3. The opening portion 34c is preferably at C2 or less. When the wafer placement table 10 is viewed from above, as indicated by the one-dot chain line arrow in FIG. 3, it is preferable that an outer edge 34c1 of the opening portion 34c and the refrigerant flow path 32 do not overlap. The base plate through-hole 34 communicates with a bonding layer through-hole 44. The bonding layer through-hole 44 is a substantially cylindrical hole penetrating the bonding layer 40 in the up-down direction and is provided at a position facing the base plate through-hole 34. In this embodiment, a distance from the outer edge 34c1 of the opening portion 34c of the base plate through-hole 34 to an inner peripheral surface 44a of the bonding layer through-hole 44 is zero.

The insulating tube 50 is housed in the base plate through-hole 34 and the bonding layer through-hole 44. The insulating tube 50 is a substantially cylindrical member made of an electrically insulating material (for example, ceramic or resin), and has an insulating tube through-hole 54 that penetrates the insulating tube 50 in the up-down direction along its central axis.

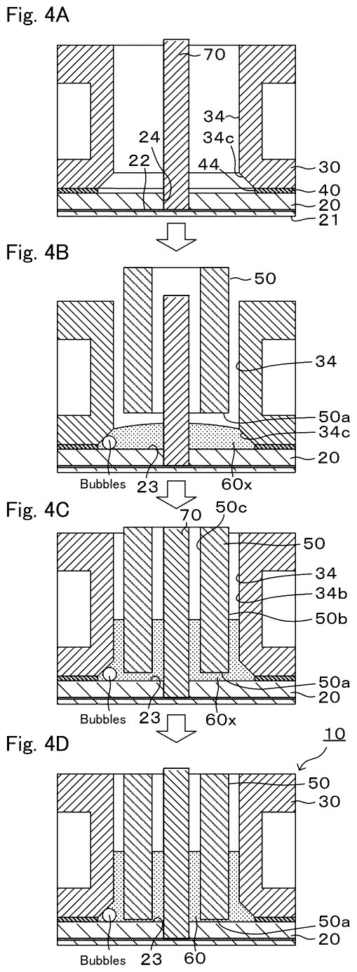

As shown in FIG. 3, the insulating tube 50 is bonded to a lower surface 23 of the ceramic plate 20 and an inner peripheral surface 34b of the base plate through-hole 34 via an adhesive layer 60. The adhesive layer 60 contains a resin. The adhesive layer 60 includes an insulating tube upper surface adhesion portion 61, an insulating tube outer peripheral surface adhesion portion 62, and an insulating tube inner peripheral surface adhesion portion 63. The insulating tube upper surface adhesion portion 61 bonds the lower surface 23 of the ceramic plate 20 and an upper surface 50a of the insulating tube 50. The insulating tube outer peripheral surface adhesion portion 62 bonds the inner peripheral surface 34b (including the opening portion 34c) of the base plate through-hole 34, the outer peripheral surface 50b of the insulating tube 50, and the lower surface 23 of the ceramic plate 20. The insulating tube inner peripheral surface adhesion portion 63 bonds an outer peripheral surface of the power feeding member 70, an inner peripheral surface 50c of the insulating tube 50, and the lower surface 23 of the ceramic plate 20. Among the insulating tube outer peripheral surface adhesion portions 62, a portion between the opening portion 34c of the base plate through-hole 34 and the outer peripheral surface 50b of the insulating tube 50 is referred to as a specific adhesion portion 62a. The specific adhesion portion 62a may have bubbles. When the specific adhesion portion 62a has bubbles, it is preferable that the bubbles exist at positions separated from the insulating tube 50 (positions not in contact with the upper surface 50a or the outer peripheral surface 50b of the insulating tube 50). One example thereof is shown in FIG. 4D. A thickness (vertical length) of the insulating tube upper surface adhesion portion 61 is preferably 0.01 mm or more and 0.1 mm or less, for example. A height (vertical length, also referred to as a climbing amount) of the insulating tube outer peripheral surface adhesion portion 62 is preferably 3 mm or more and 10 mm or less, for example. A distance (radial length) between the inner peripheral surface 34b (excluding the opening portion 34c) of the base plate through-hole 34 and the outer peripheral surface 50b of the insulating tube 50 is preferably 0.05 mm or more and 0.5 mm or less, for example. Examples of materials for the adhesive layer 60 include insulating resins such as epoxy resin, acrylic resin, and silicone resin. The adhesive layer 60 may be one in which a filler is contained in the insulating resin. The filler is preferably a material having higher thermal conductivity than the insulating resin of the adhesive layer 60, and for example, alumina or aluminum nitride may be used. A thermal conductivity of the adhesive layer 60 is preferably 0.5 W/mK or more. For example, as the adhesive layer 60, a silicone resin containing alumina filler (thermal conductivity: 2.2 W/mK) may be used.

The power feeding member 70 is, for example, a metal rod. Metals used for the power feeding member 70 include, for example, W, Mo, and Ni, and it is preferable that the thermal expansion coefficient of the metal is close to the thermal expansion coefficient of the ceramic plate 20. As shown in FIG. 3, the power feeding member 70 is inserted into the insulating tube through-hole 54 and a ceramic plate bottomed hole 24, and is electrically connected to the electrostatic electrode 22 exposed at a bottom of the ceramic plate bottomed hole 24, and supplies power to the electrostatic electrode 22. The ceramic plate bottomed hole 24 is a substantially cylindrical hole provided from the lower surface 23 of the ceramic plate 20 to the electrostatic electrode 22, and has a smaller diameter than the insulating tube through-hole 54. The power feeding member 70 is electrically insulated from the base plate 30 by the insulating tube 50 arranged in the base plate through-hole 34 and the bonding layer through-hole 44.

Next, among manufacturing methods of the wafer placement table 10, a process of bonding the insulating tube 50 will be described with reference to FIGS. 4A to 4D. FIGS. 4A to 4D are explanatory diagrams of this process. In FIGS. 4A to 4D, the wafer placement surface 21 of the ceramic plate 20 is oriented downward. FIGS. 4A to 4D are partially enlarged views in which a surrounding region of the base plate through-hole 34 is enlarged.

First, a joined body in which the ceramic plate 20 and the base plate 30 are joined by the bonding layer 40 is prepared (FIG. 4A). In this joined body, the electrostatic electrode 22 is embedded in the ceramic plate 20. Also, in this joined body, the power feeding member 70 is inserted through the base plate through-hole 34 and the bonding layer through-hole 44 into the ceramic plate bottomed hole 24, and is electrically connected to the electrostatic electrode 22. The opening portion 34c chamfered with C-chamfering is formed in the base plate through-hole 34. Next, an adhesive 60x is disposed on the lower surface 23 of the ceramic plate 20 (FIG. 4B). The adhesive 60x enters between the opening portion 34c of the base plate through-hole 34 and the lower surface 23 of the ceramic plate 20. Then, the insulating tube 50 is inserted into the base plate through-hole 34 such that an upper surface 50a of the insulating tube 50 faces the adhesive 60x. Subsequently, when the insulating tube 50 is pushed toward the ceramic plate 20 side, the adhesive 60x climbs between the lower surface 23 of the ceramic plate 20 and the upper surface 50a of the insulating tube 50, between the inner peripheral surface 34b of the base plate through-hole 34 and the outer peripheral surface 50b of the insulating tube 50, and between the outer peripheral surface of the power feeding member 70 and the inner peripheral surface 50c of the insulating tube 50 (FIG. 4C). Furthermore, when the insulating tube 50 is pushed toward the ceramic plate 20 side, a gap between the lower surface 23 of the ceramic plate 20 and the upper surface 50a of the insulating tube 50 becomes narrower. In this state, the adhesive 60x solidifies, whereby the insulating tube 50 is bonded to the ceramic plate 20 and the base plate 30 via the adhesive layer 60. In this manner, the wafer placement table 10 is obtained (FIG. 4D).

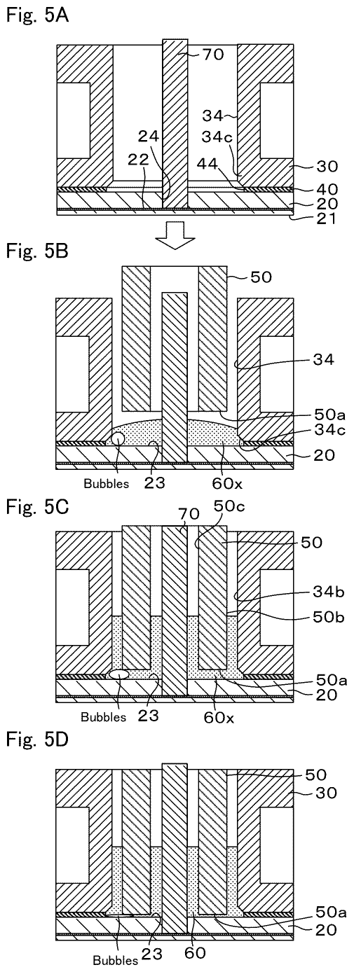

Meanwhile, bubbles may enter the adhesive 60x. In the present embodiment, the opening portion 34c chamfered with C-chamfering is at C0.5 or more. Therefore, in a process in which the insulating tube 50 is inserted into the base plate through-hole 34 such that the upper surface 50a of the insulating tube 50 faces the adhesive 60x and is pushed toward the ceramic plate 20 side (the process from FIG. 4B through FIG. 4C to FIG. 4D), bubbles generated in the adhesive 60x can escape radially outward from the upper surface 50a of the insulating tube 50. As a result, bubbles can be suppressed from entering between the lower surface 23 of the ceramic plate 20 and the upper surface 50a of the insulating tube 50. In contrast, when the opening portion 34c chamfered with C-chamfering is less than C0.5 (for example, C0.2) (comparative embodiment), the bubbles are crushed by the upper surface 50a of the insulating tube 50. FIGS. 5A to 5D are explanatory diagrams of an adhesive process of the insulating tube 50 in the comparative embodiment. FIGS. 5A to 5D correspond to FIGS. 4A to 4D. In a process in which the insulating tube 50 is inserted into the base plate through-hole 34 such that the upper surface 50a of the insulating tube 50 faces the adhesive 60x and is pushed toward the ceramic plate 20 side (the process from FIG. 5B through FIG. 5C to FIG. 5D), bubbles generated in the adhesive 60x cannot escape radially outward from the upper surface 50a of the insulating tube 50 and are crushed by the upper surface 50a of the insulating tube 50. As a result, bubbles remain between the lower surface 23 of the ceramic plate 20 and the upper surface 50a of the insulating tube 50, forming a discharge path.

In practice, a wafer placement table (Example 1) in which the insulating tube 50 having an opening portion 34c at C0.5 was bonded to the ceramic plate 20 and the base plate 30 via the adhesive layer 60, a wafer placement table (Example 2) in which the insulating tube 50 having an opening portion 34c at C1 was bonded to the ceramic plate 20 and the base plate 30 via the adhesive layer 60, and a wafer placement table (Comparative Example 1) in which the insulating tube 50 having an opening portion 34c at C0.2 was bonded to the ceramic plate 20 and the base plate 30 via the adhesive layer 60 were manufactured, and cross-sections were imaged by X-ray CT to observe the adhesive layer 60. As a result, in Examples 1 and 2, bubbles were not observed in the gap between the upper surface 50a of the insulating tube 50 and the lower surface 23 of the ceramic plate 20. In contrast, in Comparative Example 1, bubbles were observed in the gap between the upper surface 50a of the insulating tube 50 and the lower surface 23 of the ceramic plate 20. The configurations of Examples 1 and 2 and Comparative Example 1 were identical except for the difference in the C-value of the opening portion 34c.

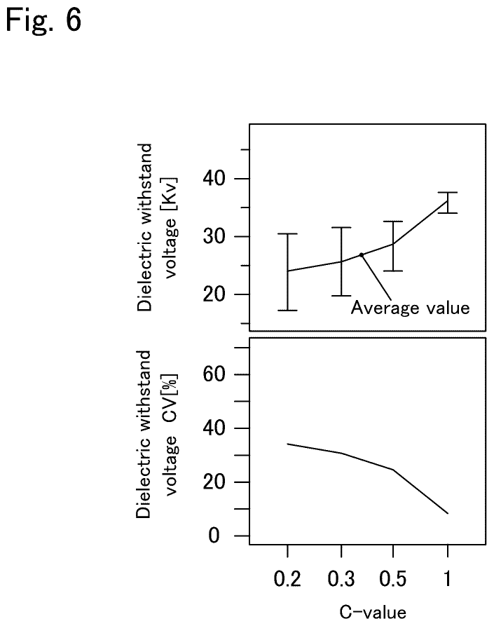

Furthermore, relationships between the C-value of the opening portion 34c and the dielectric withstand voltage, and between the C-value of the opening portion 34c and the dielectric withstand voltage CV (coefficient of variation) were examined. The dielectric withstand voltage was measured between the base plate 30 and the power feeding member 70. The C-values used were 0.2, 0.3, 0.5, and 1. For one C-value, a plurality of wafer placement tables were manufactured, and a dielectric withstand voltage of each was determined. The dielectric withstand voltage CV was obtained by dividing a standard deviation of the dielectric withstand voltage by an average value of the dielectric withstand voltage. The results are shown in FIG. 6. From FIG. 6, it was found that, if the C-value of the opening portion 34c is 0.5 or more, the dielectric withstand voltage increases and the dielectric withstand voltage CV (an indicator representing variation in dielectric withstand voltage) decreases. The samples used in the measurement of FIG. 6 had identical configurations except for the difference in the C-value of the opening portion 34c.

Next, an example of use of the wafer placement table 10 configured as described above will be explained. First, in a state where the wafer placement table 10 is installed in a chamber (not shown), a wafer W is placed on the wafer placement surface 21. Then, the chamber is depressurized by a vacuum pump to adjust a predetermined vacuum degree, and a DC voltage is applied to the electrostatic electrode 22 of the ceramic plate 20 to generate an electrostatic attraction force, thereby attracting and fixing the wafer W to the wafer placement surface 21. Next, a reaction gas atmosphere having a predetermined pressure (for example, several tens to several hundreds of Pa) is set in the chamber. In this state, an RF voltage is applied between an upper electrode (not shown) provided in a ceiling portion of the chamber and the base plate 30 of the wafer placement table 10 to generate plasma. A surface of the wafer W is processed by the generated plasma. A refrigerant is circulated as appropriate through the refrigerant flow path 32 of the base plate 30. When processing the wafer W with plasma in this manner, heat input by the plasma is removed by the base plate 30, and the wafer placement surface 21 is controlled to a desired temperature.

In the wafer placement table 10 described in detail above, the base plate through-hole 34 has, on the ceramic plate 20 side, an opening portion 34c chamfered with C-chamfering at C0.5 or more, and the adhesive layer 60 is provided between the inner peripheral surface 34b of the base plate through-hole 34 including the opening portion 34c and the outer peripheral surface 50b of the insulating tube 50. Accordingly, when inserting the insulating tube 50 into the base plate through-hole 34 and bonding it while an adhesive 60x is attached to a bottom surface (the lower surface 23 of the ceramic plate 20) of the base plate through-hole 34, even if bubbles occur in the adhesive 60x, the bubbles can sufficiently escape radially outward from the insulating tube 50, and therefore bubbles can be suppressed from entering between the upper surface 50a of the insulating tube 50 and the lower surface 23 of the ceramic plate 20. As a result, the influence of bubbles on the dielectric withstand voltage can be suppressed. Therefore, the dielectric withstand voltage between the power feeding member 70 and the base plate 30 can be increased, and even if the manner in which bubbles occur differs among products, variations in dielectric withstand voltage among products can be suppressed.

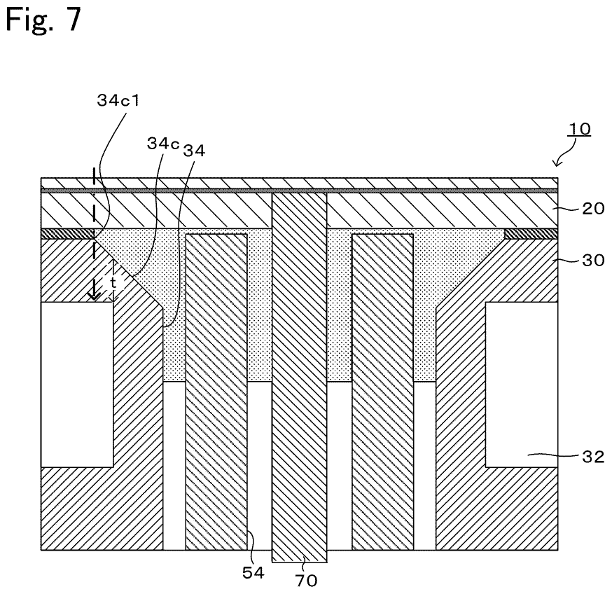

Furthermore, it is preferable that, when the wafer placement table 10 is viewed from above, the opening portion 34c of the base plate through-hole 34 and the refrigerant flow path 32 do not overlap. For example, as shown in FIG. 7, when the wafer placement table 10 is viewed from above, if the outer edge 34c1 of the opening portion 34c of the base plate through-hole 34 and the refrigerant flow path 32 overlap (see the one-dot chain line arrow), a thickness t of a portion of the base plate 30 between the opening portion 34c of the base plate through-hole 34 and the refrigerant flow path 32 tends to become thin. As a result, when the base plate 30 is pressed against the ceramic plate 20 to be joined, there is a possibility that a defect (deformation, cracking, etc.) may occur in the base plate 30. In the embodiment described above, since, when the wafer placement table 10 is viewed from above, the opening portion 34c of the base plate through-hole 34 and the refrigerant flow path 32 do not overlap, such a possibility is eliminated.

Furthermore, it is preferable that the opening portion 34c chamfered with C-chamfering is at C2 or less. A temperature of the wafer W placed on the wafer placement surface 21 tends to become high at a portion directly above a central axis of the base plate through-hole 34. When the opening portion 34c of the base plate through-hole 34 exceeds C2 (is too large), heat of the ceramic plate 20 becomes less likely to escape to the base plate 30. When the opening portion 34c chamfered with C-chamfering is at C2 or less, it is possible to suppress the tendency that heat of the ceramic plate 20 becomes less likely to escape to the base plate 30. In addition, when the opening portion 34c chamfered with C-chamfering is at C2 or less, the refrigerant flow path 32 can be brought sufficiently close to the base plate through-hole 34 within a range in which the opening portion 34c of the base plate through-hole 34 and the refrigerant flow path 32 do not overlap when the wafer placement table 10 is viewed from above.

Furthermore, the adhesive layer 60 may have bubbles between the opening portion 34c of the base plate through-hole 34 and the outer peripheral surface 50b of the insulating tube 50 (the specific adhesion portion 62a), and in such a case, the bubbles may exist at positions separated from the insulating tube 50. In this manner, the effects of the present invention are more easily achieved.

Furthermore, it is preferable that a thermal conductivity of the adhesive layer 60 is 0.5 W/mK or more. In this manner, heat of the wafer W is more easily conducted to the base plate 30 side via the adhesive layer 60, and therefore temperature uniformity of the wafer W is more easily maintained.

It should be noted that the present invention is not limited to the embodiment described above in any way, and it is needless to say that the present invention can be carried out in various modes as long as they fall within the technical scope of the present invention.

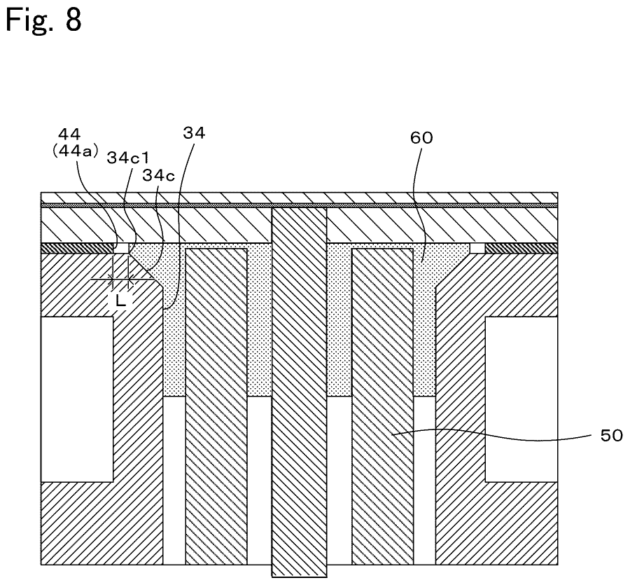

In the embodiment described above, the distance (in FIG. 8, this distance is referred to as L) from the outer edge 34c1 of the opening portion 34c of the base plate through-hole 34 to the inner peripheral surface of the bonding layer through-hole 44 was set to zero, but it is not particularly limited thereto. For example, the distance L may be 0.5 mm or less. If the distance L is 0.5 mm or less, even if a space exists between the outer edge 34c1 of the opening portion 34c of the base plate through-hole 34 and the inner peripheral surface of the bonding layer through-hole 44, an influence on temperature uniformity of the wafer W can be reduced. Specifically, it is possible to suppress a difference between a temperature of a portion of the wafer W directly above the central axis of the base plate through-hole 34 and a temperature on a circumference of a circle of diameter 30 mm centered on that portion to a predetermined temperature (for example, 10° C.) or less. When the distance L exceeds 0.5 mm (for example, if it is 0.6 mm), a space between the outer edge 34c1 of the opening portion 34c of the base plate through-hole 34 and the inner peripheral surface of the bonding layer through-hole 44 becomes too large, and the difference exceeds the predetermined temperature. Considering ease of entry of the adhesive into the space, the distance L is preferably 0.3 mm or less, more preferably 0.2 mm or less, and further preferably 0.1 mm or less.

In the embodiment described above, the bonding layer 40 was exemplified as a metal layer, but it is not particularly limited thereto. For example, the bonding layer 40 may be a resin layer or an inorganic adhesive may be adopted. Examples of materials for the resin layer include insulating resins such as epoxy resin, acrylic resin, and silicone resin. The bonding layer 40 may also be one in which a filler is contained in the insulating resin. The filler is preferably a material having higher thermal conductivity than the insulating resin of the bonding layer 40, and for example, alumina or aluminum nitride may be used. When adopting a bonding layer having good thermal conductivity, it is preferable that the bonding layer is a metal bonding layer.

In the embodiment described above, the electrostatic electrode 22 was incorporated in the ceramic plate 20, but it is not particularly limited thereto. For example, in place of or in addition to the electrostatic electrode 22, a heater electrode (resistive heating element) may be incorporated, or an electrode for generating plasma (RF electrode) may be incorporated.

In the embodiment described above, the adhesive layer 60 was assumed to include the insulating tube inner peripheral surface adhesion portion 63, but it is not necessary to include the insulating tube inner peripheral surface adhesion portion 63.

What is claimed is:

1. A member for semiconductor manufacturing apparatus comprising:
a ceramic plate having a wafer placement surface on its upper surface and incorporating an electrode;
a base plate which is joined to a lower surface of the ceramic plate via a bonding layer and incorporates a refrigerant flow path;
a base plate through-hole which penetrates the base plate in an up-down direction at a position not interfering with the refrigerant flow path, and which has an opening portion chamfered with C-chamfering at C0.5 or more on the ceramic plate side;
an insulating tube inserted into the base plate through-hole;
a power feeding member inserted into the insulating tube and having a tip electrically connected to the electrode; and
an adhesive layer provided between an inner peripheral surface of the base plate through-hole including the opening portion chamfered with C-chamfering and an outer peripheral surface of the insulating tube.

2. The member for semiconductor manufacturing apparatus according to claim 1,
wherein, when the member for semiconductor manufacturing apparatus is viewed from above, the opening portion of the base plate through-hole and the refrigerant flow path do not overlap each other.

3. The member for semiconductor manufacturing apparatus according to claim 1,
wherein the opening portion chamfered with C-chamfering is at C2 or less.

4. The member for a semiconductor manufacturing apparatus according to claim 1,
wherein the adhesive layer has bubbles between the opening portion of the base plate through-hole and the outer peripheral surface of the insulating tube, and the bubbles are present at positions separated from the insulating tube.

5. The member for a semiconductor manufacturing apparatus according to claim 1,
wherein the bonding layer has a bonding layer through-hole at a position facing the base plate through-hole, and a distance from an outer edge of the opening portion of the base plate through-hole to an inner peripheral surface of the bonding layer through-hole is 0.5 mm or less.

6. The member for a semiconductor manufacturing apparatus according to claim 1,
wherein thermal conductivity of the adhesive layer is 0.5 W/mK or more.
